(19) United States
(12) Patent Application Publication
(10) Pub. No.: US 2024/0392981 A1
(43) Pub. Date: Nov. 28, 2024

(54) STORAGE FACILITY

(71) Applicant: DAIFUKU CO., LTD., Osaka-shi, Osaka (JP)

(72) Inventor: Kazuya OMORI, Shiga (JP)

(73) Assignee: DAIFUKU CO., LTD., Osaka-shi, Osaka (JP)

(21) Appl. No.: 18/641,889

(22) Filed: Apr. 22, 2024

(30) Foreign Application Priority Data
May 26, 2023 (JP) 2023-087219

(51) Int. Cl. F24F 3/167

(52) U.S. Cl. CPC F24F 3/167; F24F 2221/14

(57) ABSTRACT

An object is to keep cleanliness in a storage facility even in a case where clean air is unevenly fed to the storage facility from above the storage facility. A storage facility (1) that is to be provided in a clean room (CR) into which clean air is fed from a fan filter unit (FFU) provided to a ceiling (100) so that cleanliness in the clean room is kept, the storage facility (1) including: a storage shelf (2) in which a container (50) is to be placed; and a plurality of holes (4) provided at least in a position (P) where a ceiling of the storage shelf (2) is constituted, the plurality of holes (4) allowing the clean air fed from the fan filter unit (FFU) into the clean room (CR) to pass therethrough so that the clean air flows in the storage facility (1).

This Nonprovisional application claims priority under 35 U.S.C. § 119 on Patent Application No. 2023-087219 filed in Japan on May 26, 2023, the entire contents of which are hereby incorporated by reference.

### TECHNICAL FIELD

The present invention relates to a storage facility.

### BACKGROUND ART

According to a known conventional technology, in order to store products (e.g., semiconductors and/or liquid crystal substrates) for which high cleanliness needs to be kept, a storage shelf for storing the products is provided in a clean room. For example, Patent Literature 1 discloses a storage shelf provided with a rectifying means. After the air (clean air) is blown from a ceiling of a clean room and is divided into portions flowing to the front and back sides of the storage shelf having a ceiling, the air flowing downward is guided by the rectifying means toward the storage shelf.

### CITATION LIST

### Patent Literature

Patent Literature 1
Japanese Patent Application Publication, Tokukai, No. 2002-338007

### SUMMARY OF INVENTION

### Technical Problem

For a clean room, there has been a method for feeding clean air into a clean room from a fan filter unit provided to a ceiling of the clean room, so as to keep cleanliness of the air in the clean room. Depending on the air cleanliness required for the clean room, an area in which the fan filter unit is provided may be smaller relative to an area of the ceiling of the clean room. In such a case, an area above the storage shelf has a portion in which the fan filter unit is provided and a portion in which the fan filter unit is not provided. This causes unevenness in the flow of the clean air from the ceiling toward the storage shelf, and thus stagnation of the air is likely to occur in the storage shelf.

An aspect of the present invention has an object to keep cleanliness in a storage facility even in a case where clean air is unevenly fed to the storage facility from above the storage facility.

### Solution to Problem

In order to attain the object, a storage facility in accordance with an aspect of the present invention is a storage facility that is to be provided in a clean room into which clean air is fed from a fan filter unit provided to a ceiling of the clean room so that cleanliness of air in the clean room is kept, the storage facility including: a storage shelf in which an article is to be placed; and a plurality of holes provided at least in a position where a ceiling of the storage shelf is constituted, the plurality of holes allowing the clean air fed from the fan filter unit into the clean room to pass therethrough so that the clean air flows in the storage facility.

### Advantageous Effects of Invention

In accordance with an aspect of the present invention, it is possible to keep cleanliness in a storage facility even in a case where clean air is unevenly fed to the storage facility from above the storage facility.

### BRIEF DESCRIPTION OF DRAWINGS

FIG. 1 is a longitudinal cross-sectional view of a storage facility in accordance with an embodiment of the present invention.

FIG. 2 is a horizontal cross-sectional view of the storage facility.

FIG. 3 is a front view of the storage facility.

FIG. 4 is a back view of the storage facility.

FIG. 5 is a view illustrating a position of an area where fan filter units are provided, the area being included in a ceiling of a clean room in which the storage facility is provided.

FIG. 6 is a view illustrating a flow of the air in the storage facility.

FIG. 7 is a top view of example arrangement of a perforated plate of the storage facility.

FIG. 8 is a view illustrating (i) a result of an airflow analysis on the inside of the storage facility and (ii) a result of an airflow analysis on the inside of a conventional storage facility.

FIG. 9 is a table showing results of measurements of an oxygen concentration in the storage facility, the measurements being carried out with perforated plates having different aperture rates.

### DESCRIPTION OF EMBODIMENTS

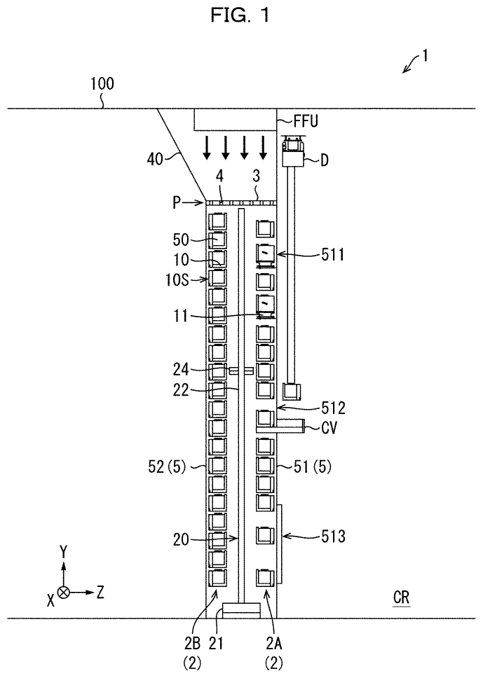

The following will give a detailed description of an embodiment of the present invention. Note, however, that the following description is made for a mere example of a storage facility 1 in accordance with the present invention, and the technical scope of the present invention is not limited to examples in the drawings. For simplicity of description, the following description that, relative to the storage facility 1 shown in FIG. 1, a longitudinal direction is a Y-axis direction, a direction extending from a back surface 52 of the storage facility 1 to a front surface 51 of the storage facility 1 is a Z-axis direction, and a direction perpendicular to the Y-axis and Z-axis is an X-axis direction

### [Overview of Storage Facility]

A product for which high cleanliness needs to be kept, such as a semiconductor or a liquid crystal substrate, may be stored in a storage facility provided in a clean room CR into which clean air is fed from a fan filter unit (hereinafter, referred to as a “FFU”) provided to a ceiling 100 so that cleanliness of the air in the clean room is kept.

In this case, if an area above the storage facility has a portion in which the FFU is provided and a portion in which the FFU is not provided, this causes unevenness in the flow of the clean air from above the storage facility toward the storage facility. Consequently, the clean air would not be introduced into the storage facility in an even flow, and thus the clean air would not flow evenly also in the storage facility and stagnation is likely to occur in the storage facility. This makes it difficult to keep cleanliness in the storage facility.

FIG. 1 is a longitudinal cross-sectional view of the storage facility 1 in accordance with an embodiment of the present invention, taken along a plane which is in parallel to the Y-axis and Z-axis. As shown in FIG. 1, the storage facility 1 is provided in the clean room CR into which clean air is fed from the FFU provided to the ceiling 100 so that cleanliness in the clean room is kept, and includes a storage shelf 2 in which a container 50 is to be placed. Further, at least in a position P where a ceiling of the storage shelf 2 is constituted, there provided a plurality of holes 4 allowing the clean air fed from the FFU into the clean room CR to pass therethrough so that the clean air flows in the storage facility 1.

Thanks to this, even in a case where the flow of the clean air from above the storage facility 1 toward the storage facility 1 is uneven, the storage facility 1 can allow the clean air to be fed into the storage facility 1 in an even flow, which makes it possible to allow the clean air to flow in the storage facility 1 in an even flow. As a result, it is possible to realize the storage facility 1 that can suppress or reduce generation of stagnation of the air in the storage facility 1 and thus can keep cleanliness in the storage facility 1.

### [Storage Facility]

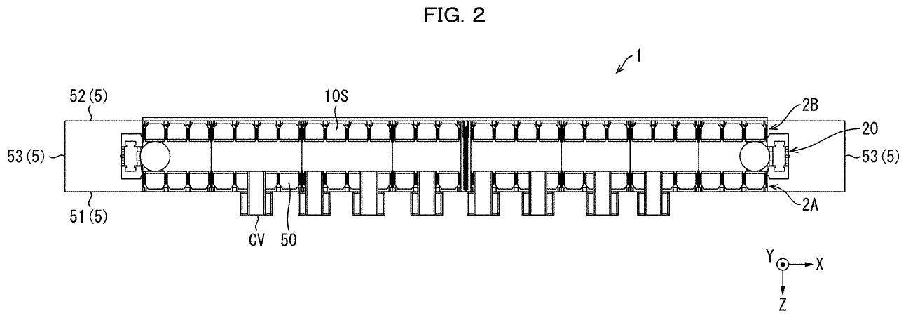

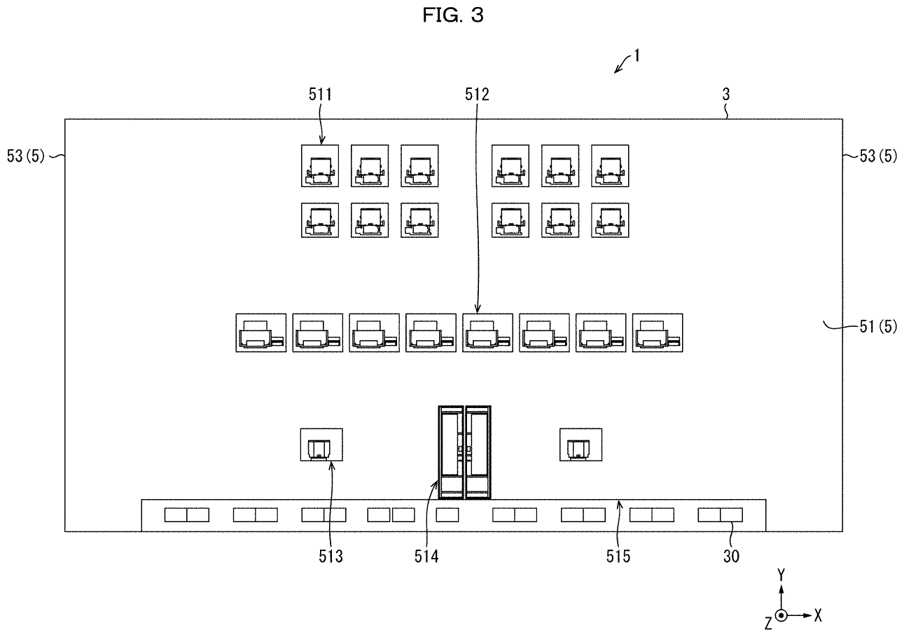

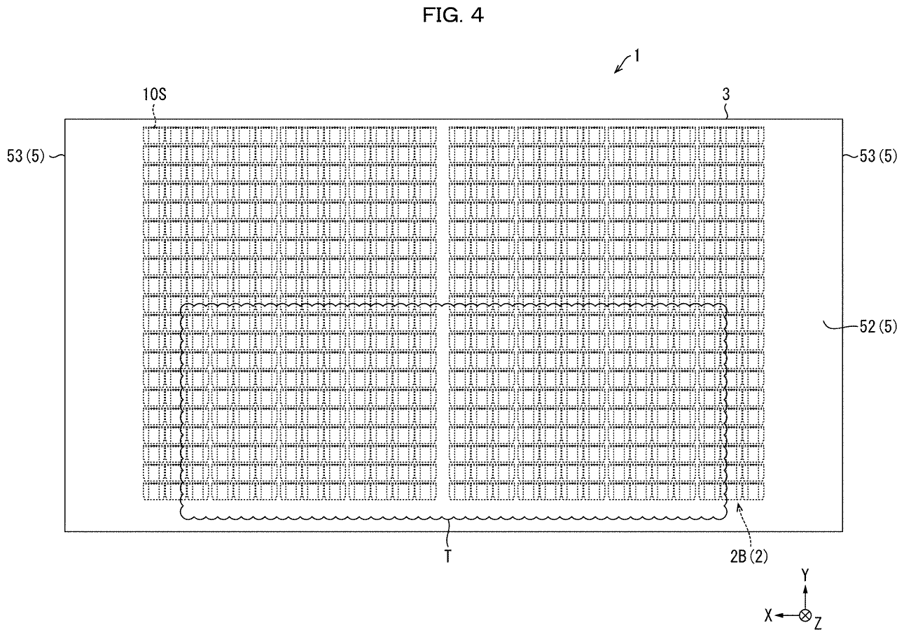

FIG. 2 is a horizontal cross-sectional view of the storage facility 1, taken along a plane which is in parallel with the X-axis and Z-axis. FIG. 3 is a front view of the storage facility 1. FIG. 4 is a back view of the storage facility 1. For easy understanding, FIG. 4 shows storage parts 10S of the storage facility 1 by broken lines.

As shown in FIGS. 1 to 4, the storage facility 1 is provided in the clean room CR. The clean room CR keeps cleanliness of the air in the clean room by allowing clean air from the FFU provided to the ceiling 100 to be fed into the room. The FFU feeds the clean air into the clean room CR such that the clean air flows from the ceiling 100 of the clean room CR toward a floor surface of the clean room CR.

The storage facility 1 includes the storage shelf 2, the perforated plate 3, a side part 5, a stacker crane 20, an exhaust part 30, and a cover 40.

### (Storage Shelf)

In the storage shelf 2, the container(s) 50 (article(s)) is/are to be placed. The storage shelf 2 includes storage parts 10S in which the container(s) 50 is/are to be housed. The storage parts 10S are arranged in the Y-axis direction and the X-axis direction.

Each container 50 is used to house a semiconductor, a liquid crystal substrate, or the like, and is a Front Opening Unified Pod (FOUP), for example. The container 50 has an upper surface provided with a flange which can be grasped by a hoist-type carrier vehicle D. The container 50 has a bottom surface having an engagement groove with which a positioning pin engages. The container 50 is configured such that, when the container 50 is housed in the storage part 10S, a position to be positioned is determined by a positioning pin provided to an upper surface of a placement table 10 of the storage part 10S.

Further, the container 50 has a structure for introducing nitrogen gas serving as inert gas. For example, the container 50 has a gas inlet and a gas outlet, each of which is not illustrated. The gas inlet has an introduction-side opening/closing valve, and the gas outlet has an exhaust-side opening/closing valve. Each of the introduction-side opening/closing valve and the exhaust-side opening/closing valve is biased toward a closing side by a biasing means such as a spring. The introduction-side opening/closing valve is configured to open when a discharge pressure of nitrogen gas fed to the gas inlet becomes equal to or higher than a first predetermined pressure which is higher than an atmospheric pressure. The exhaust-side opening/closing valve is configured to open when a pressure inside the container 50 becomes equal to or higher than a second predetermined pressure which is higher than an atmospheric pressure. As the container 50, an airtight container made of synthetic resin can be employed, for example.

Each of the plurality of storage parts 10S is configured to house the container 50 therein. Each of the plurality of storage parts 10S has a plate-shaped placement table 10 on which the container 50 can be placed and which can support the container 50. The placement table 10 has an upper surface provided with the above-mentioned positioning pin.

The storage part 10S has a structure for introducing nitrogen gas into the container 50. For example, the placement table 10 has a discharge nozzle for feeding nitrogen gas into the inside of the container 50 and an exhaust tube for discharging gas in the container 50. The discharge nozzle is connected with a feeding tube through which nitrogen gas from a given part is to be fed. The exhaust tube has an end which is opposite to an end closer to the container 50 and which is open at a location close to its respective storage part 10S in the storage facility 1. Consequently, excess nitrogen gas is discharged from the container 50 to the inside of the storage facility 1.

Note that some of the plurality of storage parts 10S in the storage shelf 2 may be storage parts 10S configured to allow nitrogen gas to be introduced thereinto. In this case, the container 50 having a structure for introducing nitrogen gas is placed in the storage part 10S having a structure for introducing nitrogen gas into the container 50.

As shown in FIG. 2, the storage shelf 2 has a pair of storage shelves 2A and 2B facing each other. Assuming that a direction in which delivery of the container 50 with respect to the stacker crane 20 is carried out is an inner side, the storage shelves 2A and 2B are arranged so as to face each other at a distance of a given interval in substantially parallel with each other along the X-axis direction. The stacker crane 20 (described later) is provided between the storage shelves 2A and 2B.

The side part 5 surrounds a region where the storage shelves 2A and 2B and the stacker crane 20 are provided. The side part 5 has a front surface 51, a back surface 52 facing the front surface 51, and a pair of side surfaces 53 via which the front surface 51 and the back surface 52 are connected to each other at two ends of the front surface 51, the two ends facing each other in the X-axis direction. As shown in FIG. 2, the back surface 52 and the pair of side surfaces 53 have no opening. Meanwhile, as shown in FIG. 3, the front surface 51 has openings 511, 512, 513, 514, and 515. The storage facility 1 is provided such that the back surface 52 lies along a wall of the clean room CR.

Each of the openings 511, 512, and 513 is an opening allowing the container 50 to pass therethrough in order that the container 50 is carried from the outside of the storage facility 1 to the inside of the storage facility 1 or in order that the container 50 is carried from the inside of the storage facility 1 to the outside of the storage facility 1. At a location which is inward of the storage facility 1 and adjacent to the opening 511, a load receiving table 11 for delivery of the container 50 is provided. For example, the container 50 is carried from the storage part 10S by the stacker crane 20, so as to be placed on the load receiving table 11. Then, the container 50 is picked up by the carrier vehicle D, and is then carried to a given position.

For the opening 512, a conveyor CV is provided such that the conveyor CV extends through the opening 512. For example, the container 50 carried by the carrier vehicle D is placed on the conveyor CV, and the container 50 is conveyed from the outside of the storage facility 1 to the inside of the storage facility 1 by the conveyor CV; then, the container 50 is carried to any one of the plurality of storage parts 10S by the stacker crane 20.

At a location which is inward of the storage facility 1 and adjacent to the opening 513, a load receiving table (not illustrated) for delivery of the container 50 is provided. For example, the container 50 is carried from the storage part 10S by the stacker crane 20, so as to be placed on the load receiving table. Then, a person picks up the container 50 and carries the container 50 to a given position. At the opening 513, work is carried out by human. Thus, the opening 513 has an opening/closing part which can be opened and closed with respect to the opening 513.

The opening 514 is an opening through which a work person can go in and go out from the storage facility 1 for the purpose of maintenance of the storage facility 1, for example. The opening 514 also has an opening/closing part which can be opened and closed with respect to the opening 514. The opening 515 is provided in a lower end of the front surface 51 so as to extend along the X-axis direction. The opening 515 functions as a gas outlet of the exhaust part 30 (described later).

### (Stacker Crane)

The stacker crane 20 (see FIGS. 1 and 2) is configured to be capable of carrying the containers 50 to the plurality of storage parts 10S and the openings 511, 512, and 513. As shown in FIG. 1, the stacker crane 20 includes: a traveling carrier 21 capable of traveling along a traveling rail (not illustrated) provided in an area of a floor which area is sandwiched between the storage shelves 2A and 2B; a mast 22 provided to the traveling carrier 21 in a standing manner; and a lifting table 24 moving upward and downward along the mast 22.

Note that the lifting table 24 is provided with a transfer device (not illustrated) for transferring the container 50 to the storage part 10S or the like. The transfer device includes a plate-shaped placement supporter on which the container 50 can be placed and which can support the container 50. The placement supporter moves between a protruded position which is protruded toward the inside of the storage part 10S and a retraction position which is retracted toward the lifting table 24. As a result of movement of the placement supporter and a lifting action of the lifting table 24, the container 50 on the placement supporter is housed in the storage part 10S or the container 50 housed in the storage part 10S is taken out to the placement supporter. The placement supporter is configured to be capable of protruding also toward the opening 511, the load receiving table of the opening 513, and the conveyor CV extending through the opening 512.

### (Exhaust Part)

As shown in FIG. 3, the exhaust part 30 is provided in a lower portion of the front surface 51, and externally discharges the air inside the storage facility 1. The exhaust part 30 allows the clean air introduced from the FFU through the holes 4 to efficiently flow from an upper part of the storage facility 1 to a lower part of the storage facility 1, thereby making it possible to evenly and favorably flow the clean air in the storage facility 1. Further, providing the exhaust part 30 makes it possible to suppress or reduce occurrence of a phenomenon that the air flows out of the storage facility 1 through the openings 511, 512, 513, and 514. In the present embodiment, the number of the exhaust parts 30 is 17 (see FIG. 3). However, this is not limitative. The number of the exhaust parts 30 and an air volume are set as appropriate according to the size of the storage facility 1.

### (Perforated Plate)

The perforated plate 3 is provided at least in the position P where the ceiling of the storage shelf 2 is constituted. The perforated plate 3 has the plurality of holes 4 through which the clean air fed from the FFU into the clean room CR passes so that the clean air flows in the storage facility 1.

The position P where the ceiling of the storage shelf 2 is constituted indicates a position of an upper part of the storage shelf 2 in the storage facility 1. The position P where the ceiling of the storage shelf 2 is constituted may coincide with the position where the ceiling of the storage facility 1 is constituted. For example, the perforated plate 3 may be provided so as to cover an area extending from an upper side of the front surface 51 to an upper side of the back surface 52, as shown in FIG. 1. In other words, the perforated plate 3 may be provided in the entire position where the ceiling of the storage facility 1 is constituted. The perforated plate 3 is not limited to the above-described one. The perforated plate 3 may be provided at least in the position P where the ceiling of the storage shelf 2 is constituted, and an area where the perforated plate 3 is provided may be set as appropriate.

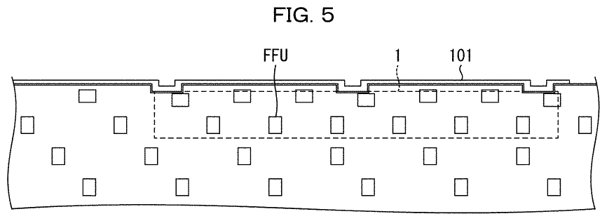

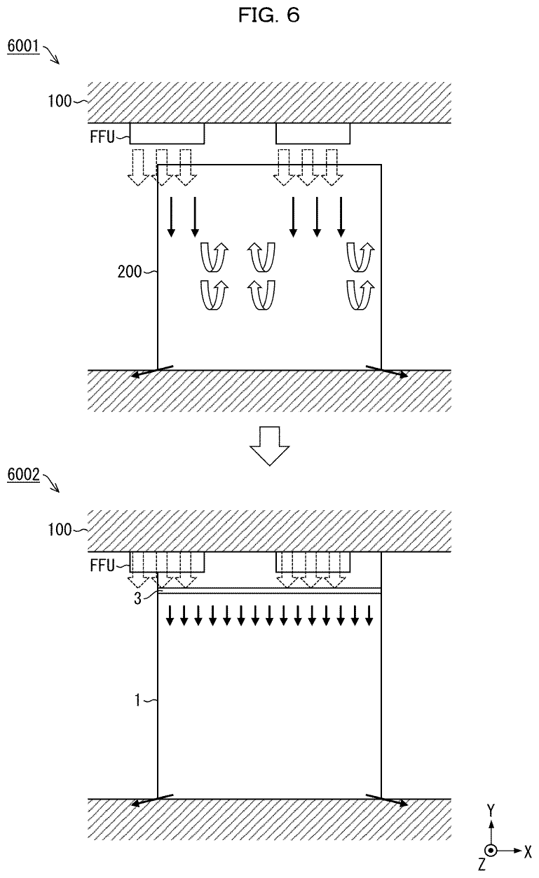

FIG. 5 is a view illustrating a position, in the ceiling of the clean room CR in which the storage facility 1 is provided, where the FFU is provided. For easy understanding, a position in the clean room CR in which position the storage facility 1 is provided is indicated by broken lines in FIG. 5. As shown in FIG. 5, the storage facility 1 is arranged along a wall 101 of the clean room CR. FIG. 6 is a view illustrating the flow of the air in the storage facility 1 and the flow of the air in the storage facility 200. 6001 of FIG. 6 illustrates the flow of the air in the conventional storage facility 200 without a ceiling, and 6002 of FIG. 6 illustrates the flow of the air in the storage facility 1.

The number of FFUs provided in the clean room CR is determined according to the cleanliness. As shown in FIG. 5, the ceiling 100 above the storage facility 1 (storage facility 200) may have a portion in which the FFU is provided and a portion in which the FFU is not provided. In this case, there is a possibility that the flow of the clean air from above the storage facility 200 toward the storage facility 200 may become uneven and consequently the clean air may be introduced into the storage facility 200 in an uneven flow.

Here, the expression that “the flow of the clean air from above the storage facility 200 toward the storage facility 200 is uneven” means that, in a region corresponding to an area of the storage facility 200 viewed in a plan view (hereinafter, such a region will be referred to as a “facility footprint of the storage facility 200”), a flow velocity of the clean air observed when the clean air reaches the storage facility 200 is uneven.

The expression that “the clean air is introduced into the storage facility 200 in an uneven flow” means that, in the facility footprint of the storage facility 200 viewed in a plan view, a flow velocity of the clean air observed when the clean air passes through the position where the ceiling of the storage facility 200 is constituted is uneven.

When the clean air is introduced into the storage facility 200 in an uneven flow, the air may flow upward in some portions of the storage facility 200, as shown in 6001 of FIG. 6. This may cause, for example, a situation that particles generated in the stacker crane 20 may be stirred up to an upper part of an interior of the storage facility 200 and consequently cleanliness in the storage facility 200 may be deteriorated.

Meanwhile, since the storage facility 1 is provided with the perforated plate 3 at least in the position P where the ceiling of the storage shelf 2 is constituted, the clean air is introduced into the storage facility 1 through the holes 4 after the clean air fed from the FFU to the clean room CR reaches the storage facility 1. Thus, even in a case where the clean air is fed from the ceiling 100 toward the storage facility 1 in an uneven flow, the perforated plate 3 can rectify the flow of the clean air and the clean air can be introduced into the storage facility 1 so that the flow of the clean air in the storage facility 1 is even. With this, as shown in 6002 of FIG. 6, the flow of the clean air in the storage facility 1 becomes even. This makes it possible to suppress or reduce occurrence of stagnation of the air in the storage facility 1.

Here, the expression that “the clean air can be introduced into the storage facility 1 so that the flow of the clean air in the storage facility 1 is even” means that, in the facility footprint of the storage facility 1 in a plan view, the clean air is introduced into the storage facility 1 so that the flow velocity of the clean air passing through the perforated plate 3 is almost even. The expression that “the flow of the clean air in the storage facility 1 is even” means that, in the facility footprint of the storage facility 1 at each height of the facility footprint 1, the flow velocity of the clean air is almost even.

Meanwhile, in a case where nitrogen gas is introduced into the container 50, if the air locally having low oxygen concentration leaks out of the storage facility 1 through the opening(s) 511, 512, 513, and/or 514, there is a risk that a work person and/or the like in an area surrounding the storage facility 1 may inhale the air with low oxygen concentration. This is unfavorable.

In contrast, if the clean air is introduced into the storage facility 1 so that the flow of the clean air in the storage facility 1 is even, this can suppress or reduce a phenomenon that the oxygen concentration is drastically reduced locally in the storage facility 1. Consequently, it is possible to suppress or reduce a phenomenon that the air with very low oxygen concentration is discharged to the outside of the storage facility 1 through the opening 511 and/or the like.

There is no particular limitation on a hole diameter, a pitch, and an aperture rate of the holes 4 of the perforated plate 3. However, the hole diameter is preferably not less than 30 and not more than 50, particularly preferably 50. The pitch of the holes 4 is preferably not less than 4 mm and not more than 10 mm, particularly preferably not less than 8 mm and not more than 10 mm. The aperture rate is preferably set in a range of not less than 20% and not more than 40%, particularly preferably in a range of not less than 22% and not more than 36%.

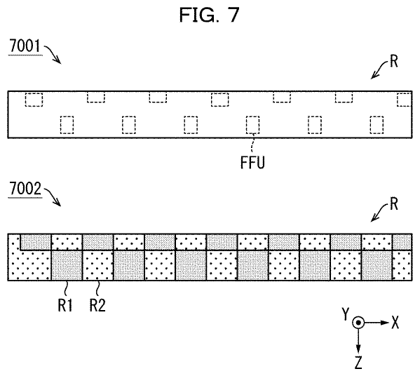

FIG. 7 is a top view of example arrangement of the perforated plate 3 of the storage facility 1. 7001 of FIG. 7 is a view illustrating only a region where the storage facility 1 is provided, the region being cut out from FIG. 5. 7002 of FIG. 7 is a top view illustrating example arrangement of the perforated plate 3 of the storage facility 1. In 7002 of FIG. 7, regions with the same hatching pattern have the same aperture rate of the holes 4. As shown in FIG. 7, a region R where the plurality of holes 4 are provided in the position P where the ceiling of the storage facility 1 is constituted includes at least a first region R1 and a second region R2. For the first region R1, a first aperture rate is set as an aperture rate of a plurality of holes 4. For the second region R2, a second aperture rate is set as an aperture rate of a plurality of holes 4, the second aperture rate being higher than the first aperture rate.

As shown in 7001 and 7002 of FIG. 7, in the storage facility 1, the region R is the entire position where the ceiling of the storage facility 1 is constituted, and the holes 4 are provided in the entire position where the ceiling of the storage facility 1 is constituted. Further, for a region corresponding to an area of the ceiling 100 in which area the FFU is provided, the first region R1 whose aperture rate is the first aperture rate is arranged. Meanwhile, for a region corresponding to an area of the ceiling 100 in which area the FFU is not provided, the second region R2 whose aperture rate is the second aperture rate is arranged. That is, the first region R1 is arranged in a portion of the region R which portion is closer to the FFU, whereas the second region R2 is arranged in a portion of the region R which portion is farther from the FFU than the first region is. In other words, in the portion of the region R which portion is farther from the FFU than the first region R1 is, an aperture rate of the perforated plate 3 is set at the second aperture rate, which is higher than the first aperture rate.

Consequently, the second region R2 farther from the FFU allows the clean air to pass therethrough into the storage facility 1 more smoothly than the first region R1 does, thereby making it possible to introduce the clean air into the storage facility 1 evenly and more favorably.

### (Cover)

Furthermore, as shown in FIG. 1, the storage facility 1 may be provided with the cover 40 by which the clean air fed from the FFU into the clean room CR is guided to a position where the ceiling of the storage facility 1 is constituted. The cover 40 extends, in an area surrounding an upper end of the storage facility 1, from the storage facility 1 at least to the ceiling 100 of the clean room CR so as to surround the FFU.

In a case where the storage facility 1 is not provided with the cover 40, the following situation may occur, for example. That is, in the clean room CR, the clean air from the FFU may flow into the region where the perforated plate 3 is not provided, which may cause reduction in an amount of the clean air introduced into the storage facility 1. With the reduced amount of the clean air fed into the storage facility 1, stagnation of the air in the storage facility 1 is likely to occur.

In contrast, by providing the cover 40 so as to connect at least a part of a clean-air feeding opening of the FFU with the storage facility 1, it is possible to reliably guide, into the storage facility 1, the clean air coming from the FFU surrounded by the cover 40. The cover 40 is not limited to the above. Alternatively, the cover 40 may be configured to extend from the floor surface to the ceiling 100 of the clean room CR so as to surround the storage facility 1 and the FFU.

### [Airflow Analysis]

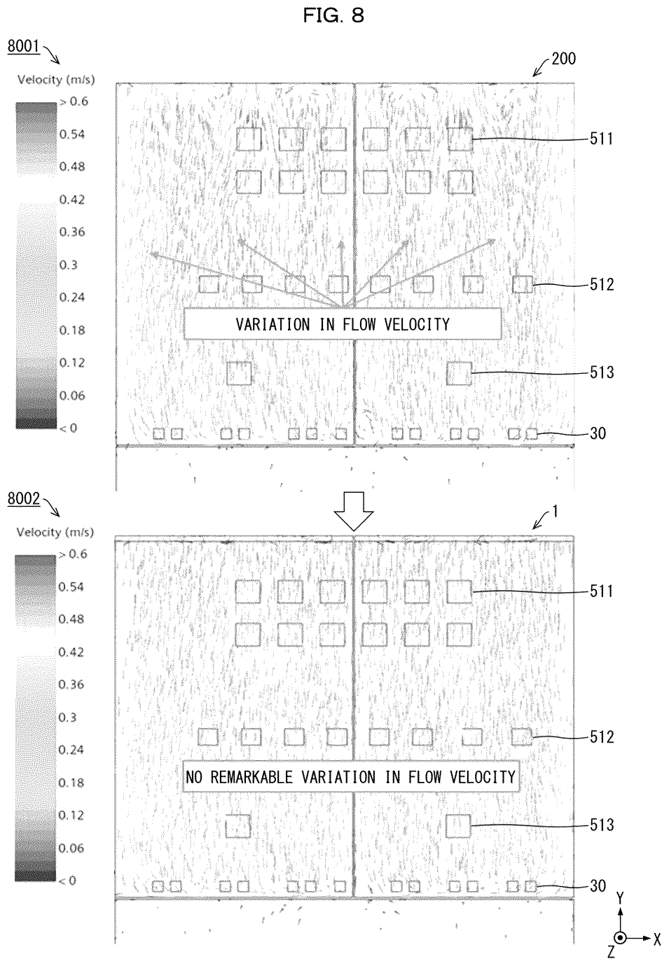

FIG. 8 is a view illustrating (i) a result of an airflow analysis on the inside of the storage facility 1 and (ii) a result of an airflow analysis on the inside of the conventional storage facility 200. 8001 of FIG. 8 shows a result of the airflow analysis on the inside of the conventional storage facility 200, which is not provided with the perforated plate 3. Meanwhile, 8002 of FIG. 8 shoes a result of the airflow analysis on the inside of the storage facility 1, which is provided with the perforated plate 3. It is assumed that the storage facility 1 is 14835 mm in width, 8370 mm in height, and 1430 mm in depth and the FFUs are arranged as shown in the arrangement shown in FIG. 5. Further, it is assumed that the perforated plate 3 provided in the storage facility 1 is provided over the entire upper surface of the storage facility 1, and has an even aperture rate.

As shown in 8001 and 8002 in FIG. 8, a variation is observed in the flow velocity of the air in the storage facility 200, whereas no variation is observed in the flow velocity of the air in the storage facility 1. Providing, in the above-described manner, the perforated plate 3 in the position where the ceiling of the storage shelf 2 is constituted makes the flow of the air in the storage facility 1 even. From this, it is understood that this can suppress or reduce occurrence of stagnation of the air in the storage facility 1.

### [Oxygen Concentration]

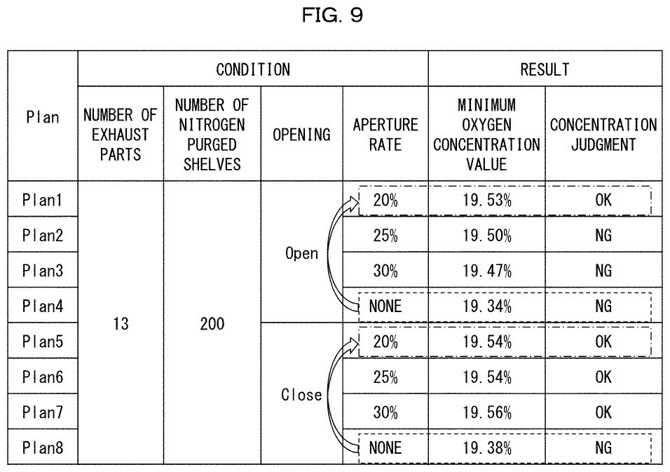

FIG. 9 is a table showing results of measurements of a minimum value of an oxygen concentration in the storage facility 1, the measurements being carried out with perforated plates 3 having different aperture rates. In the measurements in FIG. 9, the conditions such as the size of the storage facility 1 and the arrangement of the FFUs were the same as those in the above-described airflow analysis and the number of exhaust parts 30 was 13. Further, storage parts 10S into which nitrogen gas was to be introduced were 200 storage parts 10S located in an area T (shown in FIG. 4) of the storage shelves 2A and 2B. In the measurements, a minimum value of an oxygen concentration in the air discharged from the exhaust parts 30 was measured in each of (i) cases where perforated plates 3 of different aperture rates were provided and the opening 513 was open and (ii) cases where perforated plates 3 of different aperture rates were provided and the opening 513 was closed. A concentration judgment was carried out in the following manner. That is, a case where the minimum value of the oxygen concentration was more than 19.5% was determines as “OK”, whereas a case where the minimum value of the oxygen concentration was not more than 19.5% was determined as “NG”. During the measurements shown in FIG. 9, the openings 511, 512, and 515 were open and the opening 514 was closed in the storage facility 1.

In Plan1 to Plan4, the minimum value of the oxygen concentration was measured in a state where the opening 513 was open. The measurement was carried out in each of (i) cases where perforated plates 3 having aperture rates of 20%, 25%, and 30% were provided in the entire upper surface of the storage facility 1 and (ii) a case where no perforated plate 3 was provided in the storage facility 1. According to the results of Plan1 to Plan4, the concentration judgement was “OK” only in the case where the perforated plate 3 having an aperture rate of 20% was provided.

In Plan5 to Plan8, the oxygen concentration was measured in a state where the opening 513 was closed. The measurement was carried out in each of (i) cases where perforated plates 3 having aperture rates of 20%, 25%, and 30% were provided in the entire upper surface of the storage facility 1 and (ii) a case where no perforated plate 3 was provided in the storage facility 1. According to the results of Plan5 to Plan8, the concentration judgement was “OK” in the cases where the perforated plates 3 having aperture rates of 20%, 25%, and 30% were provided.

According to the results shown in FIG. 9, it is shown that providing the perforated plate 3 makes it possible to suppress or reduce occurrence of reduction in the oxygen concentration in a state where the opening 513 is closed. Further, it is shown that, also in a state where the opening 513 is open, providing the perforated plate 3 and setting the aperture rate at 20% can suppress reduce occurrence of reduction in the oxygen concentration.

### SUMMARY

A storage facility (1) in accordance with a first aspect of the present invention is a storage facility (1) that is to be provided in a clean room (CR) into which clean air is fed from a fan filter unit (FFU) provided to a ceiling (100) of the clean room (CR) so that cleanliness of air in the clean room (CR) is kept, the storage facility (1) including: a storage shelf (2) in which an article (container 50) is to be placed; and a plurality of holes (4) provided at least in a position (P) where a ceiling of the storage shelf (2) is constituted, the plurality of holes (4) allowing the clean air fed from the fan filter unit (FFU) into the clean room (CR) to pass therethrough so that the clean air flows in the storage facility (1).

According to the above configuration, when the clean air fed from the fan filter unit (FFU) into the clean room (CR) reaches the storage facility (1), the clean air is introduced into the storage facility (1) through the holes (4) provided in the position where the ceiling of the storage shelf (2) is constituted. With this, for example, by appropriately setting the position to provide the holes (4), it is possible to allow the clean air to flow inside the storage facility (1) in an even flow, thereby making it possible to suppress or reduce occurrence of stagnation of the air in the storage facility (1). Consequently, it is possible to keep cleanliness in the storage facility (1).

A storage facility (1) in accordance with a second aspect of the present invention may be configured such that, in the first aspect, a region (R) where the plurality of holes (4) are provided in the position (P) where the ceiling of the storage shelf (2) is constituted includes at least (i) a first region (R1) for which a first aperture rate is set as an aperture rate of the plurality of holes (4) and (ii) a second region (R2) for which a second aperture rate is set as an aperture rate of the plurality of holes (4), the second aperture rate being higher than the first aperture rate, and the second region (R2) is farther from the fan filter unit (FFU) than the first region (R1) is.

According to the above configuration, in the second region (R2) farther from the fan filter unit (FFU), the plurality of holes (4) are provided at a higher aperture rate than in the first region (R1) closer to the fan filter unit (FFU). Consequently, the second region (R2), which is farther from the fan filter unit (FFU), allows the clean air to pass therethrough into the storage facility (1) more smoothly than the first region (R1) does, thereby making it possible to introduce the clean air into the storage facility (1) more favorably in an even flow.

A storage facility (1) in accordance with a third aspect of the present invention may be configured such that, in the first or second aspect, the storage facility (1) further includes: a side part (5) surrounding a periphery of the storage facility (1); and an exhaust part (30), provided in a lower portion of the side part (5), that externally discharges air inside the storage facility (1).

According to the above configuration, it is possible to externally discharge the air in the storage facility (1) via the exhaust part (30). This can cause the clean air introduced from the fan filter unit (FFU) through the holes (4) to efficiently flow from an upper part of the storage facility (1) to a lower part of the storage facility (1), thereby making it possible to flow the clean air in the storage facility (1) more favorably in an even flow.

A storage facility (1) in accordance with a fourth aspect of the present invention may be configured such that, in any one of the first to third aspects, the storage facility (1) further includes: a cover (40) by which the clean air fed from the fan filter unit (FFU) into the clean room (CR) is guided to the position where the ceiling of the storage shelf (2) is constituted, wherein the cover (40) extends, in an area surrounding an upper end of the storage facility (1), from the storage facility (1) at least to the ceiling (100) of the clean room (CR) so as to surround the fan filter unit (FFU).

According to the above configuration, it is possible to connect, via the cover (40), a clean-air feeding opening of the fan filter unit (FFU) with the position where the ceiling of the storage facility (1) is constituted. Consequently, it is possible to reliably feed, into the storage facility (1), the clean air coming from the fan filter unit (FFU) surrounded by the cover (40).

The present invention is not limited to the embodiments, but can be altered by a skilled person in the art within the scope of the claims. The present invention also encompasses, in its technical scope, any embodiment derived by combining technical means disclosed in differing embodiments. Further, it is possible to form a new technical feature by combining the technical means disclosed in the respective embodiments.

### REFERENCE SIGNS LIST

1: storage facility
2, 2A, 2B: storage shelf
3: perforated plate
4: hole
5: side part
30: exhaust part
40: cover
50: container (article)
100: ceiling of clean room
CR: clean room
FFU: fan filter unit
R: region where a plurality of holes are provided
R1: first region
R2: second region

1. A storage facility that is to be provided in a clean room into which clean air is fed from a fan filter unit provided to a ceiling of the clean room so that cleanliness of air in the clean room is kept, the storage facility comprising:
a storage shelf in which an article is to be placed; and
a plurality of holes provided at least in a position where a ceiling of the storage shelf is constituted, the plurality of holes allowing the clean air fed from the fan filter unit into the clean room to pass therethrough so that the clean air flows in the storage facility.

2. The storage facility according to claim 1, wherein:
a region where the plurality of holes are provided in the position where the ceiling of the storage shelf is constituted includes at least (i) a first region for which a first aperture rate is set as an aperture rate of the plurality of holes and (ii) a second region for which a second aperture rate is set as an aperture rate of the plurality of holes, the second aperture rate being higher than the first aperture rate; and
the second region is farther from the fan filter unit than the first region is.

3. The storage facility according to claim 1, further comprising:
a side part surrounding a periphery of the storage facility; and
an exhaust part, provided in a lower portion of the side part, that externally discharges air inside the storage facility.

4. The storage facility according to claim 1, further comprising:
a cover by which the clean air fed from the fan filter unit into the clean room is guided to the position where the ceiling of the storage shelf is constituted, wherein
the cover extends, in an area surrounding an upper end of the storage facility, from the storage facility at least to the ceiling of the clean room so as to surround the fan filter unit.
